(19) United States
(12) Patent Application Publication
(10) Pub. No.: US 2010/0015534 A1
(43) Pub. Date: Jan. 21, 2010

(54) METHOD FOR MONITORING PHOTOLITHOGRAPHY PROCESS AND MONITOR MARK

(76) Inventors: Chien-Min Wu, Hsinchu City (TW); Chien-Chih Chen, Hsinchu City (TW)

Correspondence Address: NORTH AMERICA INTELLECTUAL PROPERTY CORPORATION, P.O. BOX 506, MERRIFIELD, VA, 22116, US

(21) Appl. No.: 12/174,646

(22) Filed: Jul. 17, 2008

(51) Int. Cl. G03F 1/00; G03F 7/20

(52) U.S. Cl. 430/5; 430/322

(57) ABSTRACT

A method for monitoring a photolithography process includes providing a monitor mark having high sensitivity of the focus of the photolithography process, transferring the monitor mark together with the product patterns through the photolithography process onto a substrate, and measuring the deviation dimension of the monitor mark formed on the substrate to real-time monitor the focus of the photolithography process.

### BACKGROUND OF THE INVENTION

1. Field of the Invention

The present invention relates to a monitor mark and a method for monitoring a photolithography process by utilizing the monitor mark, and more particularly, to a monitor mark and method for monitoring the photolithography process by measuring the line-end shortening dimension.

2. Description of the Prior Art

Semiconductor devices are manufactured through morn than a hundred of semiconductor processes, wherein the various circuit layouts on the semiconductor wafers have to be defined by performing a plurality of photolithography processes. To execute a photolithography process, the surface of the semiconductor wafer is coated with a photoresist layer, and an exposure process is performed by using a photomask to form mask patterns with the predetermined circuit layout on the photoresist layer. Accordingly, the chemical property of the photoresist layer changes resulted from the exposure process. Then, a development process may be performed to remove portions of the photoresist layer exposed or not exposed by light from the semiconductor wafer so as to form a circuit layout pattern corresponding to the pattern of the photomask. Usually, the quality of the photolithography process depends on the accuracy of focus of the photolithography system. If the focus of the photolithography process is shifted or deviated (or called “defocus”), the accuracy and critical dimension (CD) of the exposed pattern will be affected, causing the exposed patterns on upper or lower layers of the semiconductor wafer to be formed in incorrect locations and influencing the semiconductor wafer to be defective.

As mentioned above, if the focus aberration of a photolithography process occurs, the accuracy of the photolithography patterns formed on the semiconductor wafer will be quite affected, and therefore the various process parameters of the photolithography equipment, including the deviation of the focus, has to be checked regularly. Currently, the method of monitoring the focus parameters of the equipments for the manufactures includes forming geometry patterns as alignment marks on the photomask, and measuring the dimension of the photolithography pattern of the geometry patterns to determine whether the photolithography process is executed at an optimum focus. However, the dimension deviation after photolithography process of this conventional mark pattern only shows little variation and little sensitivity to the focus deviation, and only one focus point can be measured in one time. Furthermore, the conventional method may need to fabricate a test mark for finishing the monitoring process, thus the total process cost is expensive. In addition, the prior-art method for managing the focus of the photolithography equipment cannot provide a function of real-time monitoring the process conditions nor real-time announcing the result or adjusting the process parameters according to the monitoring result, which effects the product quality, yield, and cost.

### SUMMARY OF THE INVENTION

It is a primary objective of the claimed invention to provide a monitor mark disposed on a photomask and a method for real-time monitoring a photolithography process by use of the monitor mark to solve the above-mentioned problem that the focus of the photolithography process equipment cannot be real-time monitored, which effects the total fabrication yield and cost.

According to the claimed invention, a method for monitoring a photolithography process comprises providing a photomask with a monitor mark having at least a set of line-end monitor pattern, providing a photolithography system that is capable of performing the photolithography process for transferring a pattern of the photomask to a substrate, providing a process parameter database including a relationship between an line-end shortening dimension of the set of the line-end monitor pattern after the photolithography process and the focus of the photolithography system, performing the photolithography process for transferring the pattern of the photomask to the substrate to form at least a photolithography mark pattern corresponding to the monitor mark, measuring the line-end shortening dimension of the photolithography mark pattern to obtain a measuring result, and comparing the measuring result and the process parameter database to monitor whether the focus of the photolithography process deviates or not.

According to the claimed invention, a monitor mark for monitoring a photolithography process is further provided. The claimed invention monitor mark comprises at least a set of a line-end monitor pattern, having at least a straight-line pattern and at least a base pattern, wherein the base pattern is positioned at a side of a line end of the straight-line pattern. The distance between the base pattern and the line end of the straight-line pattern is defined as a spacing.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram of a photolithography system for performing a photolithography process according to the present invention.

FIG. 2 is a schematic diagram of a monitor mark according to the present invention.

FIG. 3 is a schematic diagram of a photolithography mark pattern of the monitor mark shown in FIG. 2 after a photolithography process.

FIG. 4 is a curve chart of the relationship between the focus of a photolithography system and the exposed line-end spacing of the present invention monitor mark after a photolithography process.

FIG. 5 is a schematic diagram of a monitor mark according to another embodiment of the present invention.

FIG. 6 is a schematic diagram of a photomask having the present invention monitor marks shown in FIG. 5.

FIG. 7 is a process diagram of the method for monitoring a photolithography process according to the present invention.

FIG. 8 is a process diagram of building a process parameter database according to the present invention.

### DETAILED DESCRIPTION

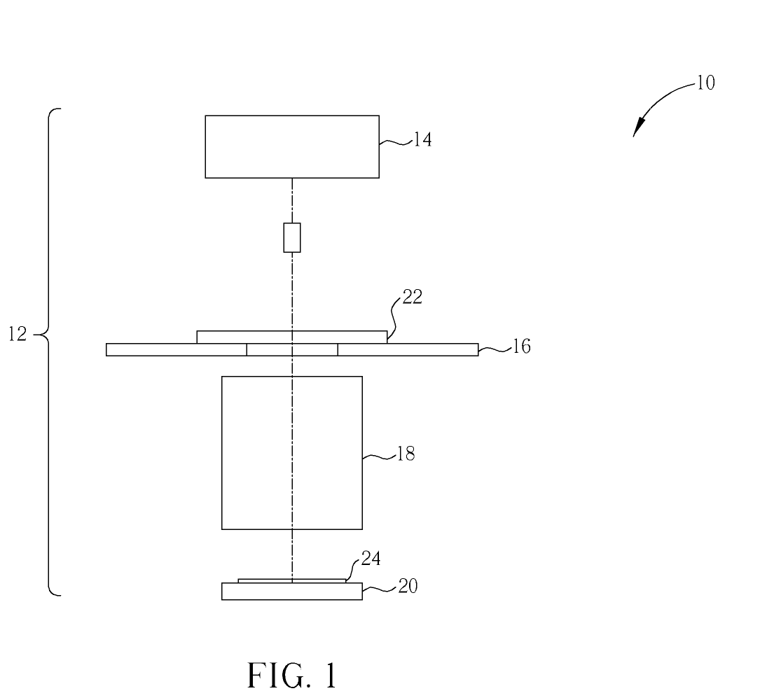

With reference to FIG. 1, FIG. 1 is a schematic diagram of a photolithography process according to the present invention. A photolithography system 10 is used for performing a photolithography process of the present invention. The photolithography system 10 may comprise a stepper 12 having a light source 14, a photomask base 16, an optical system 18, and a wafer holder 20. During performing the photolithography process, a photomask 22 with product patterns is set on the photomask base 16, and a target substrate, as a semiconductor wafer 24, is positioned on the wafer holder 20. The light source 14 of the stepper 12 provides exposure energy to lithograph the product patterns onto the photoresist material of the surface of the semiconductor wafer 24 so as to form a photolithography pattern on the photoresist material. The stepper 12 is used to shot different regions of the semiconductor wafer 24 with several times for forming pluralities of photolithography patterns corresponding to the product patterns on the surface of the semiconductor wafer 24. Then, development process, etching process, or other semiconductor processes are performed to pattern the upper layer of the semiconductor wafer 24.

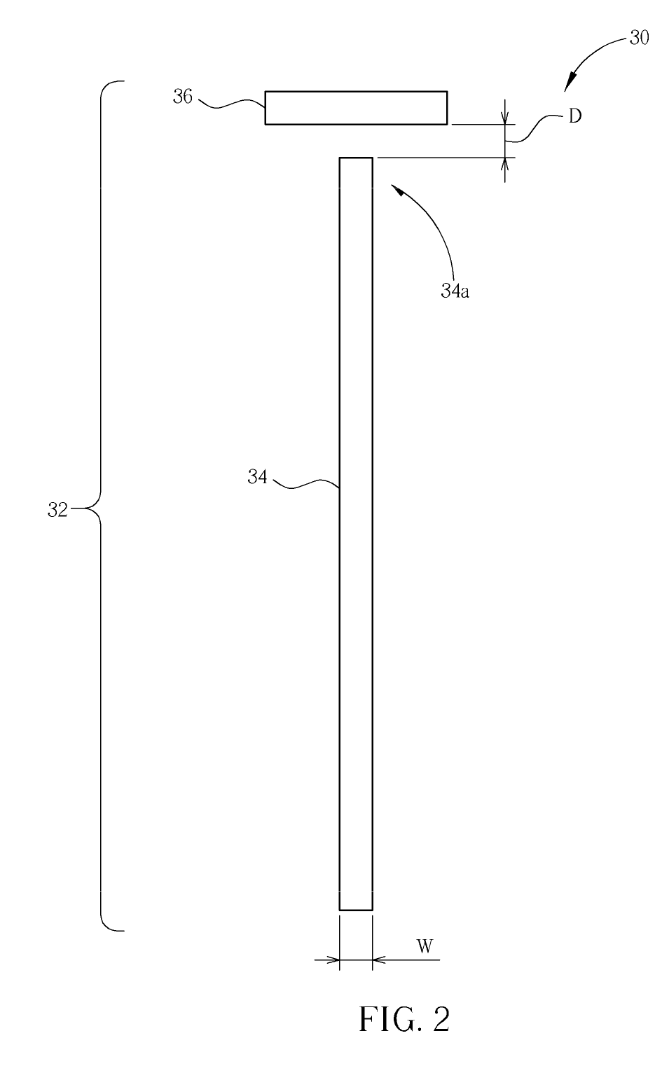

In order to monitor the photolithography system 10 for realizing whether the photolithography process is performed with a good focus, the present invention provides at least a monitor mark disposed at a side of the product pattern of the photomask 22, so as to provide the function of real-time monitoring the process parameters and yield of the photolithography system 10. Referring to FIG. 2, FIG. 2 is a schematic diagram of a monitor mark 30 according to the present invention. The monitor mark 30 may be called as a real-time focus monitor (RTFM) mark, comprising a set of line-end monitor pattern 32, wherein the line-end monitor pattern 32 has at least a straight-line pattern 34 and a base pattern 36 positioned at a side of the line end 34a of the straight-line pattern 34. The base pattern 36 preferably has a base line pattern (as shown in FIG. 2) perpendicular to the straight-line pattern 34 and having a spacing D from the line end 34a of the straight-line pattern 34. In the preferable embodiment of the present invention, the line width W of the straight-line pattern 34 may be about 0.15 micrometers to about 0.30 micrometers, and the spacing D may be about 0.5 micrometers.

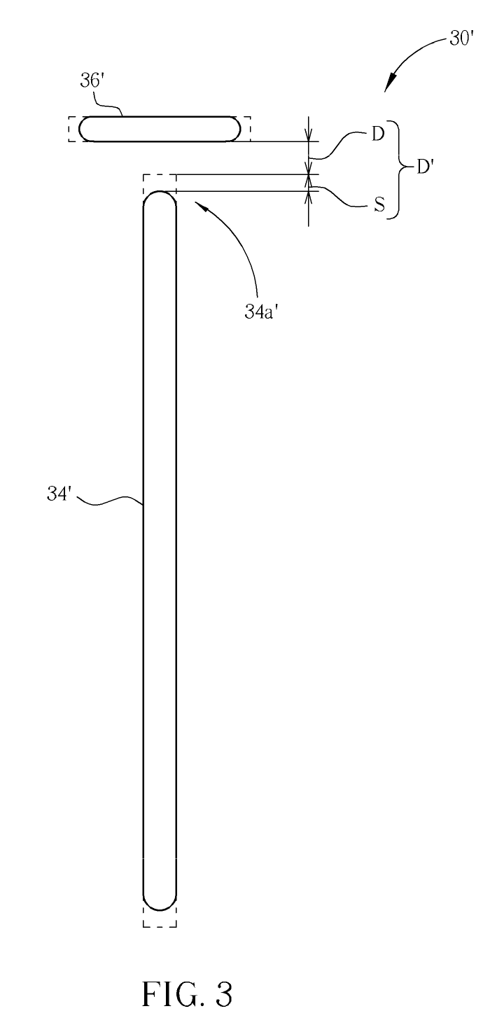

A photolithography process usually results in line-end shortening effect occurring in a photolithography pattern because of the limitation of resolution of conventional exposure equipment. Therefore, after a photolithography process, a photolithography pattern formed on the semiconductor wafer 24 of the present invention monitor mark 30 will also has a shortened line end 34a resulted from the line-end shortening effect. Please refer to FIG. 3, which is a schematic diagram of a photolithography mark pattern 30′ on a target substrate formed by the photolithography process, corresponding to the present invention monitor mark 30. The photolithography mark pattern 30′ has a photolithography straight-line pattern 34′ and a photolithography base pattern 36′, corresponding to the straight-line pattern 34 and the base pattern 36 on the photomask 22 respectively. The photolithography mark pattern 30′ further has a spacing D′ corresponding to the spacing D of the monitor mark 30. Due to the line-end shortening effect, the line end 34a′ is shortened so that the spacing D′ is larger than the original spacing D, and the spacing D′ is the sum of the spacing D and a line-end shortening dimension S. Since the line-end shortening dimension S is highly sensitive to the focus of the photolithography system 10, the line-end shortening dimension S will have a big variation if the focus of the photolithography system 10 has any little deviation. On the other words, if the deviation of the focus is larger, the line-end shortening dimension S will become larger, too. As a result, the present invention provides a method to monitor the photolithography system 10 by measuring the line-end shortening dimension S or the spacing D′ according to the above-mentioned high sensitivity of the line-end shortening dimension S.

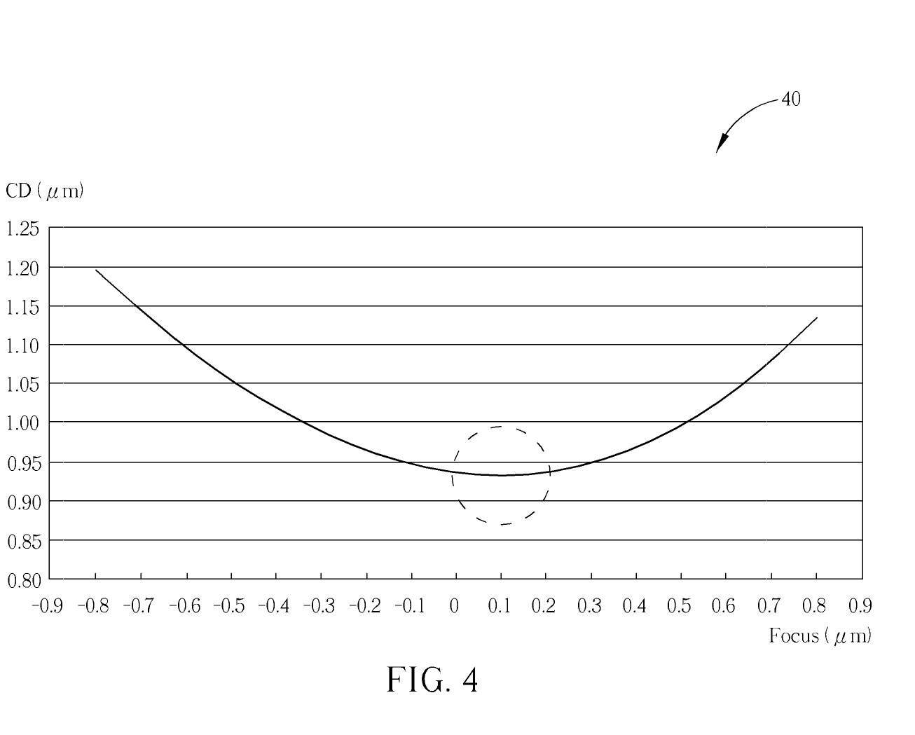

With reference to FIG. 4, FIG. 4 is a relative curve chart of the spacing D′ of the present invention RTFM mark after photolithography process versus the focus of the photolithography system, wherein the vertical axis presents the CD value of the spacing D′. As shown in FIG. 4, the spacing D′ obviously varies as the focus has any deviation, and as the aberration of the focus becomes larger, the CD value of the spacing D′ becomes larger. Furthermore, since the relative curve of the spacing D′ versus the focus of the photolithography system is a bowl-shaped arc curve, the valley or the lowest point of the relative curve can be considered as a state that the photolithography system has an optimum focus and the spacing D′ has a minimum CD value, as marked by the doted circle.

As mentioned above, the high sensitivity of the line-end monitor pattern to the photolithography system is employed by the present invention into the monitor mark. By the way of measuring the CD value of the line end spacing D′ after the photolithography process and comparing the measuring result with the curve chart shown in FIG. 4, one could realize whether the photolithography system performs a photolithography process under an optimum focus or not so as to monitor the photolithography system. For example, according to the curve chart of FIG. 4, if the photolithography process is performed as the photolithography system has a best focus of 0.1 micrometers, the CD value of the spacing D′ of the photolithography mark pattern on the target substrate should be about 0.93 micrometers. However, if the measured CD value of the spacing D′ of the photolithography mark pattern is more than 0.93 micrometers after a photolithography process, one could determine that the focus of the photolithography system has shifted or deviated. More particularly, if the measured CD value of the spacing D′ is 0.98 micrometers, one could determine the focus of the photolithography system may shift for about −0.3 or 0.45 micrometers according to the curve chart of FIG. 4. As a result, the present invention can real-time monitor the focus deviation of the photolithography system by the way of providing a process parameter database including the curve chart as FIG. 4 before the photolithography process, instantaneously measuring the spacing D′ of the photolithography mark pattern after each photolithography process, and comparing the measuring results to the process parameter database. Accordingly, if the focus deviation occurs, the process parameters of the photolithography system could be adjusted immediately so as to maintain the photolithography process under a good process condition.

It should be noted that the line-end shortening dimension S shown in FIG. 3 may be utilized as the vertical axis of the curve chart of FIG. 4 in other embodiments of the present invention, which also shows the high sensitivity and relationship of the photolithography mark pattern to the focus deviation of the photolithography system.

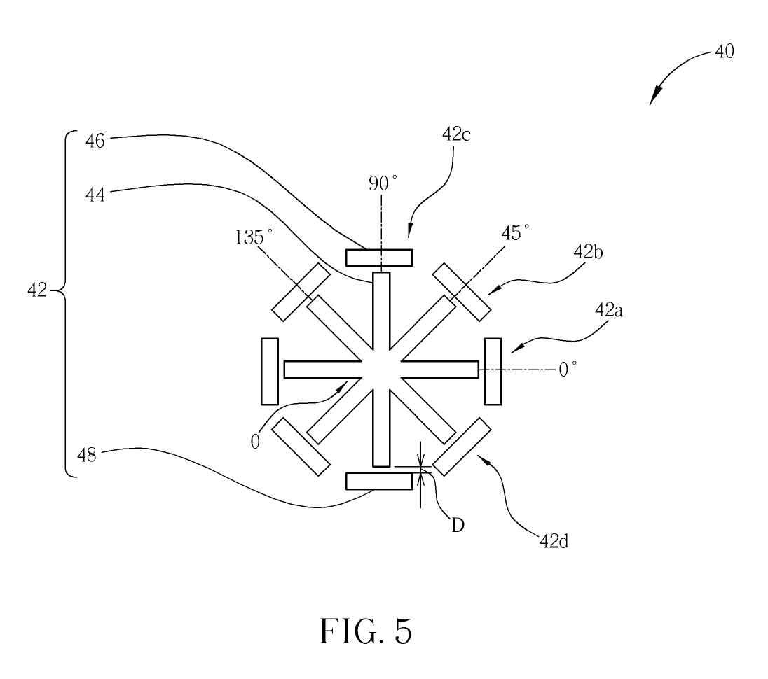

Referring to FIG. 5, FIG. 5 is a schematic diagram of a monitor mark according to a preferable embodiment of the present invention. The present invention monitor mark 40 comprises a plurality of sets of line-end monitor patterns 42 (four sets are shown in FIG. 5), and each set of the line-end monitor pattern 42 has a straight-line pattern 44 and two base patterns 46, 48. The base patterns 46 and 48 are positioned at a side of one line end of the straight-line pattern 44 respectively, each of which has a spacing D away from the straight-line pattern 44. In addition, the straight-line patterns 44 of the line-end monitor pattern 42 are not parallel with each other. For example, the straight-line patterns 44 of the four sets of line-end monitor patterns 42 may have included angles with the horizontal axis of about 0°, 45°, 90°, and 135° respectively, and intersect with each other at an intersecting point O. Furthermore, the straight-line patterns 44 are arranged radially as shape “*”, and the intersecting point O is preferably the midpoint of the straight-line patterns 44. Therefore, in order to monitor the photolithography process, all the spacings D′ of the four sets of line-end monitor patterns 42 may be measured for realizing the focus and performance of the photolithography process of different directions.

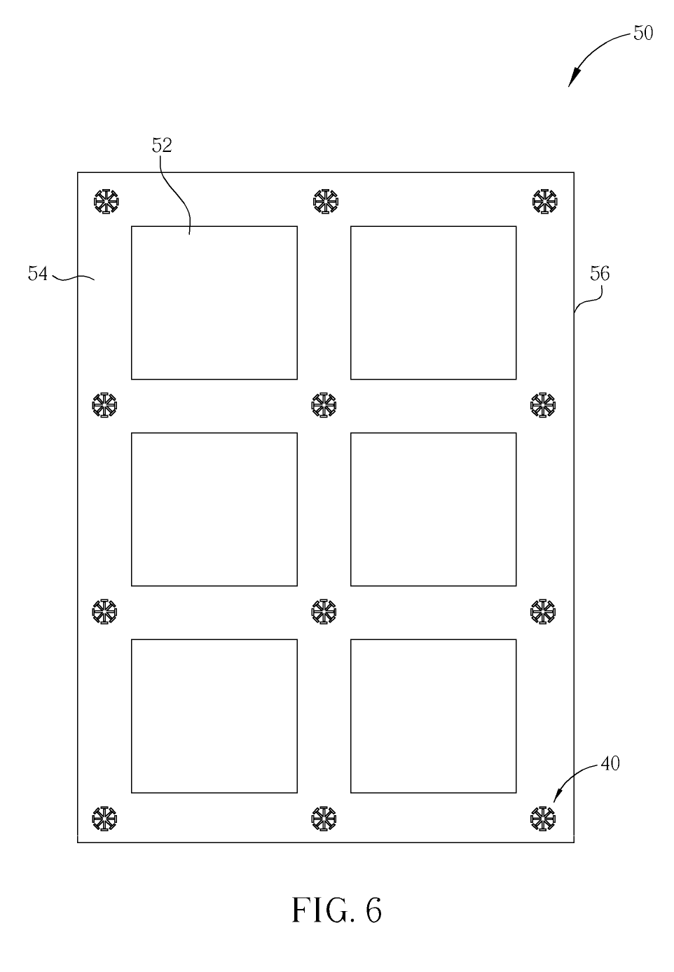

In another aspect, by using the present invention monitor mark 40 for monitoring the photolithography system 10 practically, the monitor mark 40 may be formed together with product patterns on a photomask. FIG. 6 is a schematic diagram of a photomask having the present invention monitor mark 40 shown in FIG. 5. As shown in FIG. 6, the photomask 50 comprises a shot region 56, whose pattern will be transferred onto the target substrate during one shot of the photolithography process. The shot region 56 comprises a plurality of product pattern areas 52 and at least a scribe line area 54, wherein the scribe line area 54 encompasses the product pattern areas 52. Each product pattern area 52 has product patterns (not shown) disposed therein, and the primary objective of the photolithography process includes transferring the product patterns onto the target substrate. The present invention monitor marks 40 are disposed inside the scribe line area 54 and adjacent to the product pattern areas 52, preferably at the corners, the center, or the midpoints of the center to the corners of the shot region 56. Generally, the monitor marks 40 are also disposed near the periphery of the corners of the product pattern areas 52. In FIG. 6, during a shot step of the photolithography process, the product patterns in the product pattern areas 52 and the monitor marks 40 in the scribe line area 54 are lithographed spontaneously onto the target substrate. And the shot step is repeated several times for lithographing the shot region 56 onto different portions of the target substrate to finish a whole photolithography process.

The present invention method for monitoring the focus of the photolithography process comprises utilizing a scanning electron microscopy (SEM) or other measuring instruments to measure the photolithography mark pattern formed on the target substrate after the photolithography process. For example, the CD values of the spacings D′ corresponding to the first set, second set, third set, and fourth set of the line-end monitor patterns 42a, 42b, 42c, 42d may be respectively measured if needed, and the measuring results are compared with the process parameter database, such as the curve chart shown in FIG. 4, so as to analyze the CD values of the line end spacings D′ of photolithography mark patterns for determining whether the focus shifts and the shift scale.

In this embodiment, there are at least three monitor marks 40 are disposed in different portions of the scribe line area 54 in a single shot region 56 for monitoring the deviation of the focus plane of the photolithography process. The monitoring method includes checking at least three of the photolithography mark patterns of the monitor marks 40 after a photolithography process or a shot to measure the line-end shortening dimension S or spacing D′ of each photolithography mark pattern, and comparing the measuring results with the process parameter database in order to realize if the focus plane tilts and the astigmatism issue, such as the deviation values of vertical and horizontal directions.

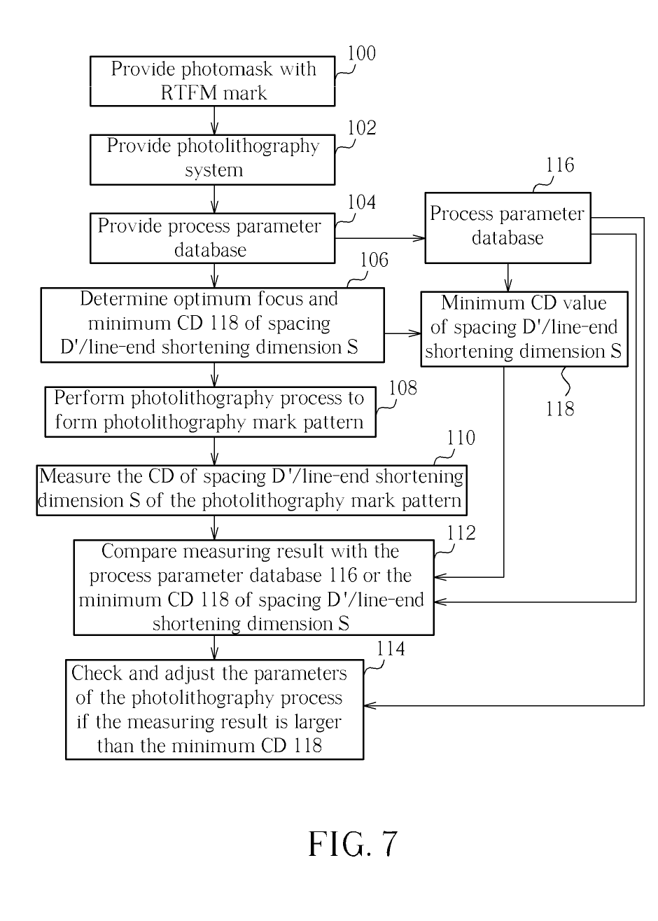

FIG. 7 is a process schematic diagram of the method for monitoring a photolithography process according to the present invention. The method includes the following steps:

Step 100: Provide a photomask having at least a product pattern and at least a present invention monitor mark (RTFM mark), wherein the present invention monitor mark comprises at least a set of line-end monitor pattern, as shown in FIG. 6. In a preferable embodiment, the present invention monitor mark comprises four sets of line-end monitor pattern shown in FIG. 5, and each set of the line-end monitor pattern has a straight-line pattern and a base pattern, wherein the distance between a line end of the straight-line pattern and the base pattern is defined as a spacing.

Step 102: Provide a photolithography system for performing a photolithography process to transfer the pattern of the photomask in Step 100 to an upper layer, such as a photoresist layer, of a target substrate, wherein a photolithography mark pattern is formed on the upper layer, which corresponds to the present invention monitor mark;

Step 104: Provide a process parameter database 116 of the photolithography system, comprising a relationship between the spacing D′ or the line-end shortening dimension S of the photolithography mark pattern and the focus of the photolithography system, as the curve chart shown in FIG. 4.

Step 106: Optionally determine an optimum focus and a minimum CD value 118 of the corresponding spacing D′ or line-end shortening dimension S according to the process parameter database 116.

Step 108: Perform a photolithography process to transfer the monitor mark of the photomask to the target substrate to obtain a photolithography mark pattern.

Step 110: Measure the CD value of the line-end shortening dimension S or spacing D′ of the photolithography mark pattern to obtain a measuring result.

Step 112: Compare the measuring result of Step 110 with the process parameter database 116 of Step 104, or compare the measuring result of Step 110 with the minimum CD value 118 of the spacing D′ or line-end shortening dimension S in order to determine whether the focus deviation of photolithography system occurs or not and the deviation scales.

Step 114: When the measuring result of Step 110 is larger than the minimum CD value 118 of the spacing D′ or line-end shortening dimension S, check and adjust the process condition and parameters of the photolithography process according to the process parameter database 116.

According to the present invention method, a statistical process control (SPC) system may be further provided, thus the comparing result in Step 112 can be send back to the SPC system. Accordingly, if the focus deviation of the photolithography process is discovered, the SPC system may immediately notice the workers or engineers during Step 114 to check or adjust the photolithography system according to the comparing result, so as to meet the objective of real-time monitoring and adjusting the process parameters of the photolithography process and to maintain the photolithography system under a preferable process condition, including the optimum focus, further to improve the product yield. On the other hand, the SPC system may record each comparing result of Step 112, and be set to detect the focus plane of the photolithography process periodically for providing a periodic analysis of the performance of the photolithography system.

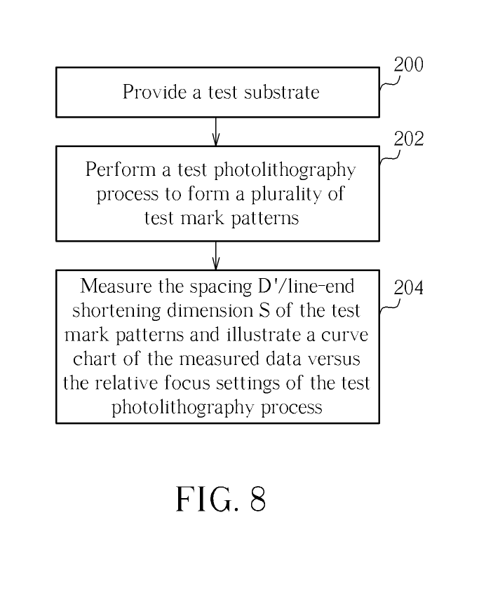

In addition, in Step 104 of providing the process parameter database 116, a standard process condition of the present invention photolithography system may be provided in advance, which includes photoresist materials and exposure conditions of the photolithography process and process parameters of the photolithography system. Sequentially, the process parameter database 116 can be built according to the standard process condition. Furthermore, the method of building the process parameter database 116 is shown in FIG. 8, comprising the following steps:

Step 200: Provide at least a test substrate.

Step 202: Perform a test photolithography process by the photolithography system, including performing several times of photolithography or exposure process with different focus settings to repeatedly lithography the pattern of the photomask of Step 100 onto the test substrate for forming a plurality of test mark patterns.

Step 204: Measure the spacing D′ or the line-end shortening dimension S of each test mark pattern on the test substrate, and illustrate a curve chart as shown in FIG. 4 by using the measured data and the relative focus settings of the test photolithography process so as to build the process parameter database 116.

On another aspect, besides real-time monitoring the focus of the photolithography system during in-line mass production by use of the present invention monitor mark, the monitor mark 40 of the present invention shown in FIG. 5 may be applied to the development of test photomask. Similarly, by disposing at least three monitor marks 40 in the scribe line area of the test photomask and performing the test photolithography process, the engineer could find out focus plane shift and tilt, lens aberration, or deviation of curvature of the photolithography process so as to improve the design of the photomask or the setting of the photolithography system.

In contrast to the prior art, the high sensitivity of line end of the straight-line pattern to the focus of the photolithography system is employed by the present invention for providing a monitor mark, which is also sensitive to the focus settings. In addition, the present invention method for monitoring the photolithography process includes disposing the monitor mark in the scribe line area of the photomask. During the photolithography or exposure process, the present invention monitor mark and the product patterns are lithographed onto the target substrate spontaneously. After each batch of wafers is lithographed in-line, the spacing or line-end shortening dimension of the line-end monitor pattern of the present invention monitor mark is measured so as to real-time find out the deviation of the focus of the photolithography system. As a result, the photolithography system does not have to be shut down during the monitoring process. Furthermore, the SPC system may be utilized to real-time check the photolithography performance for improving the yield and decreasing the fabrication cost, without affecting the production efficiency.

Those skilled in the art will readily observe that numerous modifications and alterations of the device and method may be made while retaining the teachings of the invention.

What is claimed is:

1. A method for monitoring a photolithography process, comprising:
(a) providing a photomask with a monitor mark, the monitor mark having at least a set of line-end monitor pattern;
(b) providing a photolithography system for performing the photolithography process to transfer a pattern of the photomask to a substrate;
(c) providing a process parameter database of the photolithography process, the process parameter database comprising a relationship between an line-end shortening dimension of the set of the line-end monitor pattern formed by the photolithography process and a focus of the photolithography system;
(d) performing the photolithography process for transferring the pattern of the photomask to the substrate to form at least a photolithography mark pattern on the substrate corresponding to the monitor mark;
(e) measuring an line-end shortening dimension of the photolithography mark pattern to obtain a measuring result; and
(f) comparing the measuring result and the process parameter database to monitor the deviation of the focus of the photolithography process.

2. The method of claim 1, wherein the set of line-end monitor pattern is composed of at least a straight-line pattern and a base pattern, and a distance between the base pattern and the straight-line pattern is defined as a spacing.

3. The method of claim 2, wherein the process parameter database comprises a curve chart of the spacing of the photolithography mark pattern versus the deviation of the focus of the photolithography system.

4. The method of claim 2, wherein the base pattern comprises a base line pattern perpendicular to the straight-line pattern.

5. The method of claim 2, wherein the monitor mark comprises a plurality set of the line-end monitor patterns, and the straight-line patterns of the line-end monitor patterns are not parallel with each other.

6. The method of claim 1, wherein the process parameter database comprises a line-end shortening dimension corresponding to an optimum focus of the photolithography system, and the line-end shortening dimension has a minimum value.

7. The method of claim 1, wherein the photomask comprises a product pattern area and a scribe line area, and the monitor mark is positioned in the scribe line area.

8. The method of claim 7, wherein the photomask comprises at least three monitor marks positioned in the scribe line area for monitoring an aberration of a focus plane of the photolithography system.

9. The method of claim 1, further comprising:
providing a statistical process control (SPC) system; and
sending the comparing result of step (f) to the SPC system, and immediately adjusting process parameters of the photolithography process when a focus deviation of the photolithography process occurs.

10. A monitor mark for monitoring a photolithography process, the monitor mark having at least a set of line-end monitor pattern comprising:
at least a straight-line pattern; and
at least a base pattern positioned at a side of a line end of the straight-line pattern, the base pattern and the line end of the straight-line pattern having a spacing.

11. The monitor mark of claim 10, wherein the base pattern comprises a base line pattern perpendicular to the straight-line pattern, and a distance between the base line pattern and the straight-line pattern is defined as the spacing.

12. The monitor mark of claim 10, wherein the monitor mark comprises a plurality set of the line-end monitor patterns, and the straight-line patterns of the line-end monitor patterns are not parallel with each other.

13. The monitor mark of claim 12, comprising four sets of the line-end monitor patterns, and the included angles between the straight-line patterns of the line-end monitor patterns and a horizontal axis are 0°, 45°, 90°, and 135° respectively.

14. The monitor mark of claim 13, wherein the straight-line patterns intersect with each other at an intersecting point.

15. The monitor mark of claim 14, wherein the intersecting point is a midpoint of the straight-line patterns.

16. The monitor mark of claim 14, wherein the straight-line patterns are arranged radially.

17. The monitor mark of claim 12, wherein each set of the line-end monitor pattern comprises two base patterns disposed near one of the line ends of the corresponding straight-line pattern.

18. The monitor mark of claim 10, wherein the monitor mark is disposed in a scribe line area of a photomask, and is capable of being transferred to a substrate through a photolithography process together with a product pattern of the photomask.
